(19) United States
(12) Patent Application Publication
(10) Pub. No.: US 2006/0018492 A1
(43) Pub. Date: Jan. 26, 2006

(54) Sound control system and method

(75) Inventors: Chaucer Chiu, Taipei (TW); Clark Yu, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/011,360

(22) Filed: Dec. 13, 2004

(30) Foreign Application Priority Data
Jul. 23, 2004 (TW) 093122012

(51) Int. Cl. H03G 3/00

(52) U.S. Cl. 381/104; 381/107

(57) ABSTRACT

A sound control system and method applicable to an electronic device having a timing unit. A setting module is provided to set predetermined conditions and corresponding sound volume parameters. A time session control module retrieves the sound volume parameter corresponding to a present condition obtained by the timing unit. Then, a corresponding sound output signal to be outputted by a speaker unit connected to the sound control system is set via a sound effects module according to the sound volume parameter and a sound signal around the electronic device that is received and recognized by a sound recognition module. By such arrangement, the sound control system and method allow the electronic device to provide the user with optimal sound effects depending on the environment and the user's preferences.

### FIELD OF THE INVENTION

The present invention relates to sound control systems and methods, and more particularly, to a sound control system and method applicable to an electronic device having a timing unit.

### BACKGROUND OF THE INVENTION

Consumer electronic products such as televisions are very widespread. Nowadays, watching TV programs is a principal leisure time activity associated with family life. Along with the blooming development of digital television technology, the role of TV in daily life is gradually becoming more important.

A sound control system of a traditional electronic device is based on simulation techniques, by which sound volume is adjusted via manual operation, and a user is able to adjust the sound volume depending on personal requirements. However, such sound control system is inherent with a significant drawback. The electronic device is unable to automatically adjust the sound volume according to the background noise in an environment where the electronic device is located. For example, when the user answers a phone, the sound volume needs to be decreased via manual operation. Also, there is no relationship established between the sound control of the electronic device and show times of programs played by the electronic device. For example, excessively large sound volume may disturb other people's sleep when the user listens to or watches programs at late night. The current sound control system for the electronic device does not provide a function for setting limitations on maximum sound volume according to different time sessions of a day. Additionally, there is no relationship established between the sound control and the environment where the electronic device is located. For example, it is obvious that an electronic device located in a living room would have different criteria in terms of tone quality as compared to the one located in a bedroom. However, no electronic device is currently available to automatically set or suggest optimal sound effects based on the environment. Furthermore, no relationship is established between the sound control and the user's personalized characteristics. For example, some may favor the sound effects of classical music, and some would prefer the sound effects of modern music. However, there is no electronic device being provided with a function to automatically select or suggest the optimal sound effects according to the user's personalized characteristics.

Therefore, the problem to be solved here is to provide a sound control system, which can avoid the drawbacks discussed above in the prior art.

### SUMMARY OF THE INVENTION

In light of the above prior-art drawbacks, a primary objective of the present invention is to provide a sound control system and method with a self-adaptive ability.

Another objective of the present invention is to provide a sound control system and method applicable to an electronic device having a timing unit, so as to provide a user with optimal sound effects according to an environment where the electronic device is located and the user's preferences.

In accordance with the above and other objectives, the present invention proposes a sound control system applicable to an electronic device having a timing unit. The sound control system comprises: a setting module for a user to set maximum sound volume parameters, an environmental characteristics parameter and a personalized characteristics parameter, corresponding to different time sessions of a day, an environment where the electronic device is located, and the user's personality, respectively; a parameter memory unit for storing the maximum sound volume parameters, the environmental characteristics parameter, and the personalized characteristics parameter, which are set by the user via the setting module; a time session control module for retrieving from the parameter memory unit a corresponding time session and a maximum sound volume parameter corresponding to the retrieved time session in accordance with time indicated by the timing unit; a sound recognition module for receiving and recognizing a sound signal around the electronic device; and a sound effects setting module for setting a corresponding sound output signal to be outputted by a speaker unit connected to the sound control system according to the environmental characteristics parameter, the personalized characteristics parameter, the maximum sound volume parameter retrieved by the time session control module, and the sound signal recognized by the sound recognition module.

The present invention also proposes a sound control method performed through the foregoing sound control system. The sound control method comprises the steps of: providing the setting module for a user to set maximum sound volume parameters, an environmental characteristics parameter, and a personalized characteristics parameter, corresponding to different time sessions of a day, an environment where the electronic device is located, and the user's personality, respectively; and storing the maximum sound volume parameters, the environmental characteristics parameter, and the personalized characteristics parameter in the parameter memory unit; then, retrieving via the time session control module from the parameter memory unit a corresponding time session and a maximum sound volume parameter corresponding to the retrieved time session in accordance with time indicated by the timing unit; subsequently, receiving and recognizing a sound signal around the electronic device via the sound recognition module; and finally, setting a corresponding sound output signal via the sound effects setting module according to the maximum sound volume parameter retrieved by the time session control module, the environmental characteristics parameter, the personalized characteristics parameter, and the sound signal recognized by the sound recognition module.

Compared to the prior art, the sound control system and method proposed in the present invention are advantageously capable of automatically adjusting the sound volume according to sounds in the surrounding environment, setting the maximum sound volume according to the time session of a day, and setting the tone quality according to environmental and personalized characteristics, such that the system provides the electronic device with a self-adaptive ability to control sound effects based on the objective environment and subjective preferences.

### BRIEF DESCRIPTION OF THE DRAWINGS

The present invention can be more fully understood by reading the following detailed description of the preferred embodiments, with reference made to the accompanying drawings, wherein:

FIG. 1A is a schematic block diagram showing a basic structure of a sound control system according to the present invention;

FIGS. 1B to 1E are schematic diagrams showing operation of the sound control system according to the present invention;

FIGS. 2A and 2B are flowcharts showing a sound control method performed through the sound control system according to the present invention;

FIGS. 3A and 3B are flowcharts showing a method of recognizing a sound in a surrounding environment via a sound recognition module shown in FIG. 1A;

FIG. 4 is a flowchart showing a method of setting a sound via a sound effects setting module shown in FIG. 1A; and

FIG. 5 is a table of time session versus maximum sound volume.

### DETAILED DESCRIPTION OF THE PREFERRED EMBODIMENTS

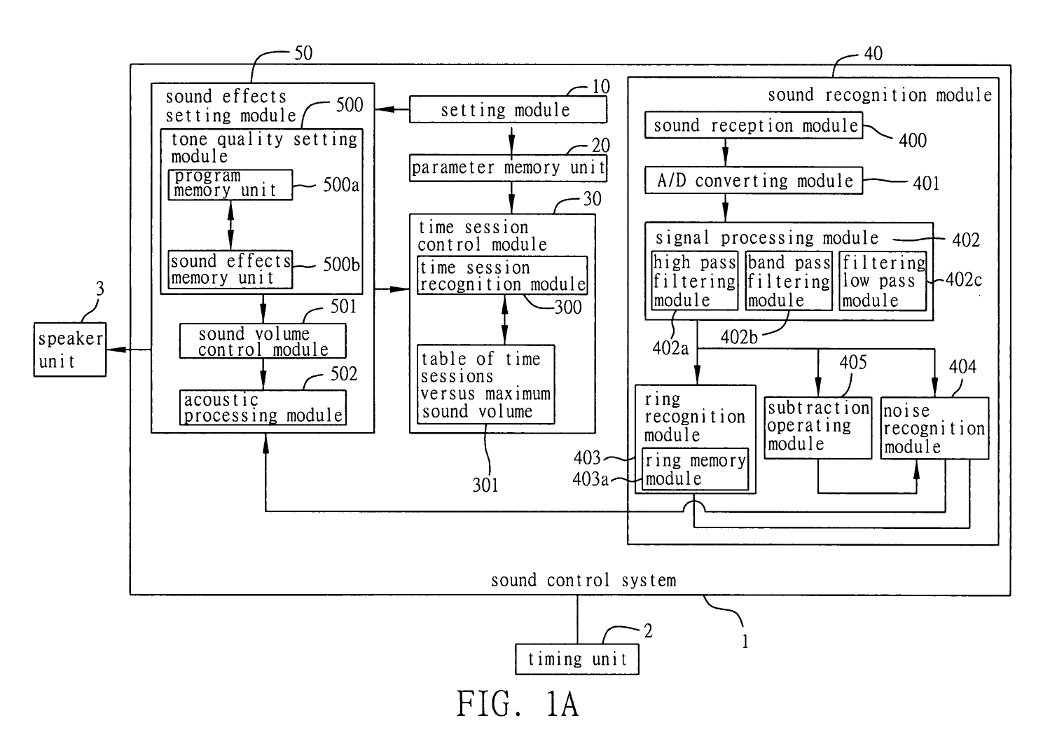

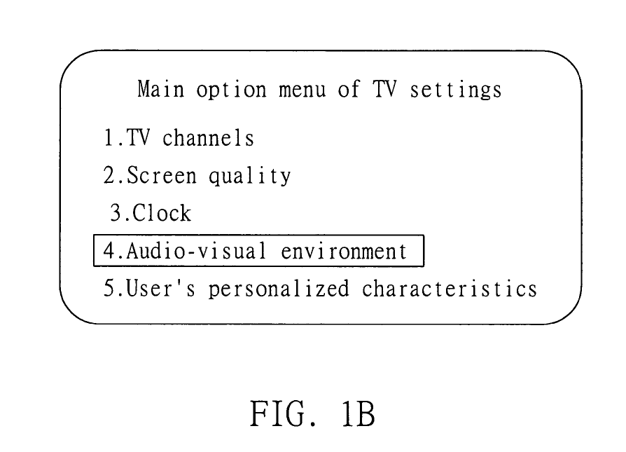

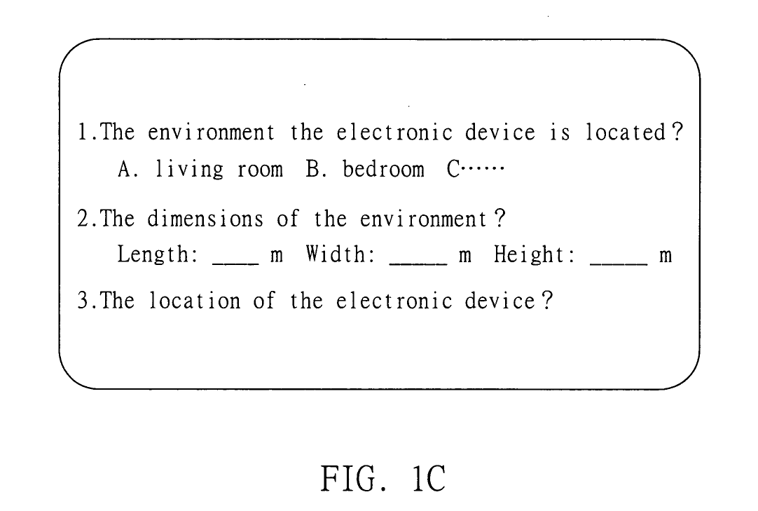

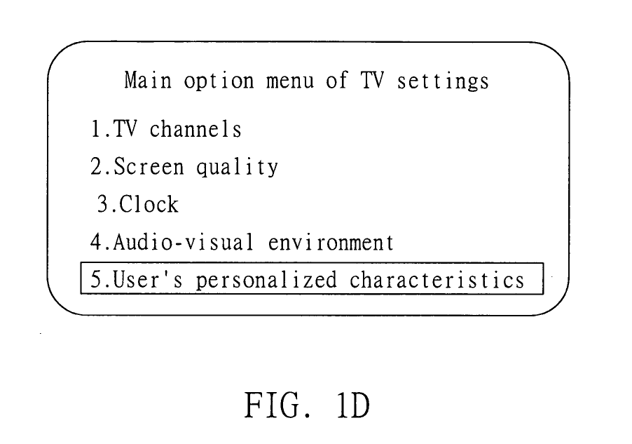

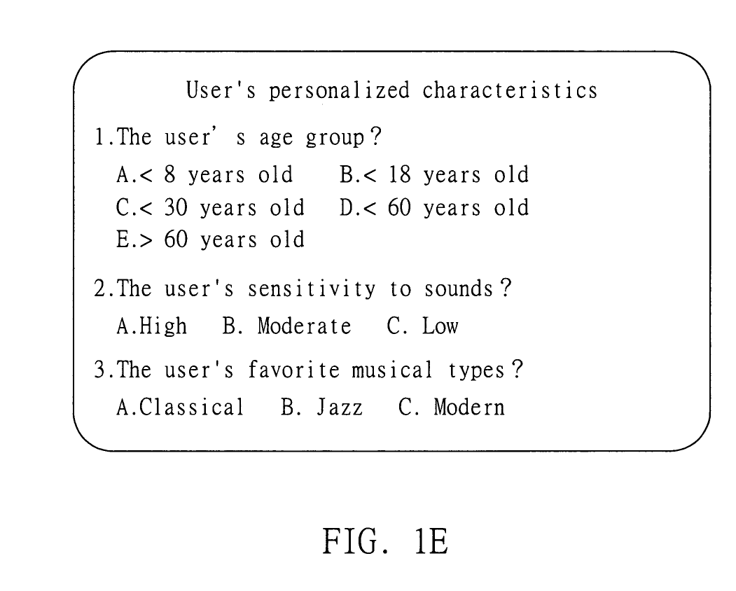

FIG. 1A is a schematic diagram showing a basic structure of a sound control system 1 according to the present invention, which is applicable to an electronic device having a timing unit 2. Referring to FIG. 1A, the sound control system 1 comprises: a setting module 10 for a user to set maximum sound volume parameters, an environmental characteristics parameter, and a personalized characteristics parameter, corresponding to different time sessions of a day, an environment where the electronic device is located, and the user's personality, respectively; a parameter memory unit 20 for storing the maximum sound volume parameters, the environmental characteristics parameter, and the personalized characteristics parameter, which are set by the user via the setting module 10; a time session control module 30 for retrieving from the parameter memory unit 20 a corresponding time session and a maximum sound volume parameter corresponding to the retrieved time session in accordance with time indicated by the timing unit 2; a sound recognition module 40 for receiving and recognizing a sound signal around the electronic device; and a sound effects setting module 50 for setting a corresponding sound output signal to be outputted via a speaker unit 3 connected to the sound control system 1 according to the maximum sound volume parameter retrieved by the time session control module 30, the environmental characteristics parameter, the personalized characteristics parameter, and the sound signal recognized by the sound recognition module 40.

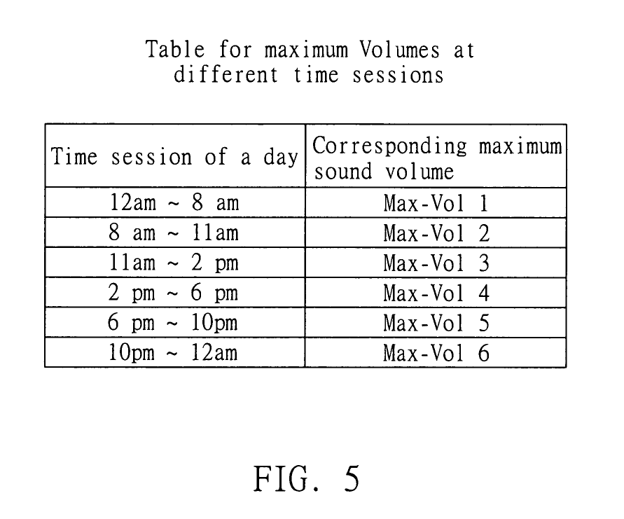

The time session control module 30 comprises a time session recognition module 300 and a table 301 of time session versus maximum sound volume. The time session recognition module 300 recognizes a corresponding time session according to the time indicated by the timing unit 2 and retrieves a maximum sound volume parameter corresponding to the retrieved time session from the table 301 of time session versus maximum sound volume (shown in FIG. 5). In the table 301, the maximum sound volume parameters corresponding to different time sessions of a day are set via the setting module 10 and proportional to the performance of sound volume of the electronic device.

The sound recognition module 40 comprises a sound reception module 400 for receiving sounds around the electronic device; an A/D converting module 401 for converting the sounds received by the sound reception module 400 to a digital signal and outputting the digital signal; a signal processing module 402 for performing a filtering process on the digital signal outputted from the A/D converting module 401; and a ring recognition module 403, a noise recognition module 404 and a subtraction operating module 405, which are respectively for recognizing a filtered signal outputted from the signal processing module 402 and outputting a sound volume control signal based on the recognition result.

The signal processing module 402 comprises a high pass filtering module 402a, a band pass filtering module 402b, and a low pass filtering module 402c, which simultaneously perform the filtering process on the digital signal outputted from the A/D converting module 401. There is a direct positive relationship between a filtering parameter for each of the filtering modules 402a, 402b, 402c and the present sound volume of the electronic device. If the present sound volume is relatively high, each of the filtering parameters is dynamically adjusted to a relatively large value. Conversely, if the present sound volume is relatively low, each of the filtering parameters is dynamically adjusted to a relatively small value.

The high pass filtering module 402a filters the digital signal to retrieve a high frequency sound signal. The ring recognition module 403 recognizes the high frequency sound signal such as a telephone ring generated in the environment and outputs a first sound volume control signal according to the recognition result.

The band pass filtering module 402b filters the digital signal to retrieve successive background sounds in the environment. The subtraction operating module 405 processes the filtered signal outputted from the band pass filtering module 402b to subtract a signal generated by the electronic device from the successive background sounds in the environment, so as to obtain successive background noises in the environment. The noise recognition module 404 recognizes and calculates the background noises in the environment, and outputs a second sound volume control signal according to the recognition result.

The low pass filtering module 402c filters the digital signal to retrieve successive noises outside the environment. The noise recognition module 404 recognizes the intensity of the noises outside the environment and outputs a third sound volume control signal according to the recognition result.

The sound effects setting module 50 comprises a tone quality setting module 500 such as a built-in sound expert digital signal processor (Sound Expert DSP) chip. The tone quality setting module 500 comprises a program memory unit 500a and a sound effects memory unit 500b. The program memory unit 500a performs a match calculation according to the environmental characteristics parameter and the personalized characteristics parameter set via the setting module 10, and retrieves a corresponding sound effects setting parameter from the sound effects memory unit 500b to determine a sound effects parameter corresponding to the characteristics of the environment and the user's personality.

Preferably, a professional tone quality program is preset in the program memory unit 500a and the sound effects memory unit 500b of the tone quality setting module 500. Referring to FIGS. 1B and 1C, the tone quality setting module 500 allows the user to select audio-visual environmental parameters including the environment where the electronic device is located (such as a living room, bedroom, or study room, etc.), the dimensions of the environment (such as length, width, and height, etc.), and/or the location of the electronic device. After the user has entered the audio-visual environmental parameters via the sound control system 1, the tone quality setting module 500 is capable of automatically setting the sound effects parameter for the environment according to the entered audio-visual environmental parameters.

Referring to FIGS. 1D and 1E, on the other hand, the tone quality setting module 500 allows the user to select the user's personalized characteristics parameters including the user's age group, the user's sensitivity to sounds (such as high-, moderate- or low-sensitivity), and/or the user's favorite musical types. Similarly, after the user has entered the user's personalized characteristics parameters via the sound control system 1, the tone quality setting module 500 is able to automatically set the sound effects parameter according to the entered user's personalized characteristics parameters.

The sound effects setting module 50 further comprises a sound volume control module 501 for setting the sound volume of the electronic device according to the first, second and third sound volume control signals outputted from the ring recognition module 403 and the noise recognition module 404; and an acoustic processing module 502 for setting a corresponding sound output signal to be outputted by the speaker unit 3 according to the sound effects parameter outputted from the tone quality setting module 500 and a sound signal of the electronic device outputted from the sound volume control module 501. Once the ring recognition module 403 has recognized a telephone ring from the high frequency sound signal, the sound volume control module 501 is capable of automatically decreasing the sound volume of the electronic device based on the first sound volume control signal, such that it would be more convenient for the user to answer the phone.

The ring recognition module 403 further comprises a ring memory module 403a for storing a telephone ring used by the user, such that the stored telephone ring can be used as a basis for the ring recognition module 403 to recognize an incoming telephone ring. The ring memory module 403a can store a plurality of different rings used by the user (such as traditional sound frequencies and pulses, or other customized-recorded rings such as music or human voices), wherein each of the different rings can be inputted several times. The ring recognition module 403 is able to identify the characteristics of each of the different rings for use as a basis in successful ring recognition. It should be understood that, the sound or voice recognition method suitable in the present invention is not limited to that disclosed in this embodiment, and the ring recognition module 403 may be applied with any sound or voice recognition method.

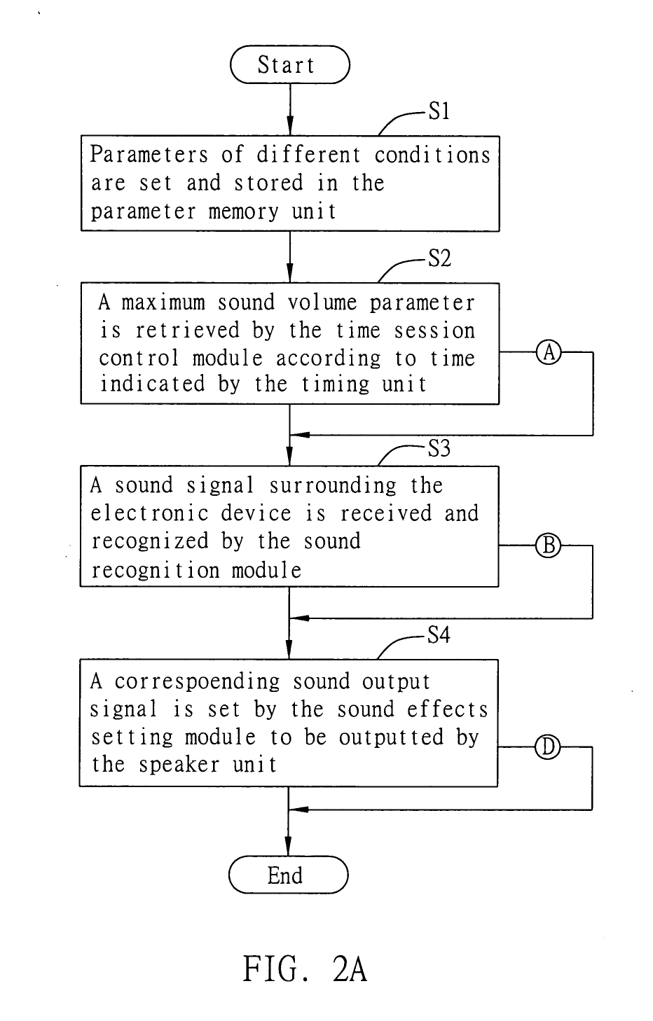

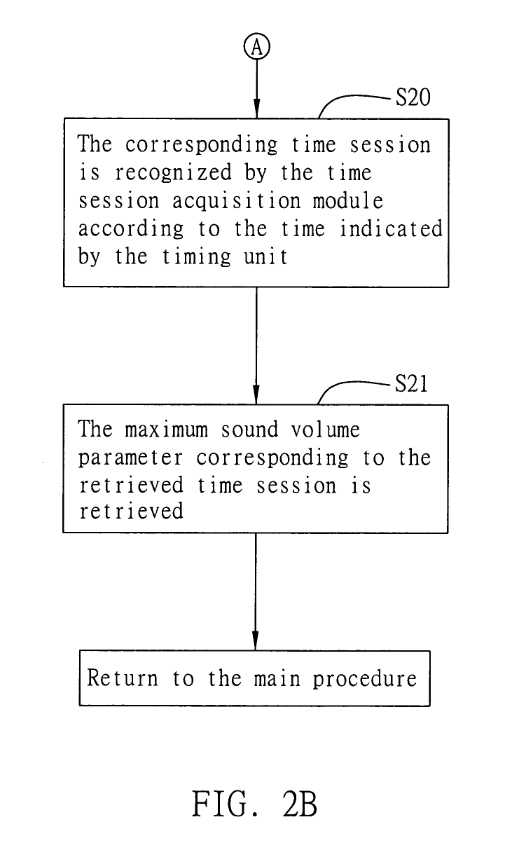

FIGS. 2A and 2B show flowcharts of a sound control method performed through the sound control system 1 according to the present invention. The sound control method comprises the following steps. In Step S1, the setting module 10 allows a user to set maximum sound volume parameters, an environmental characteristics parameter, and a personalized characteristics parameter, corresponding to different time sessions of a day, an environment where the electronic device is located, and the user's personality, respectively. The maximum sound volume parameters, the environmental characteristics parameter, and the personalized characteristics parameter are stored in the parameter memory unit 20. Then, it proceeds to Step S2.

In Step S2, the time session control module 30 retrieves from the parameter memory unit 20 a corresponding time session and a maximum sound volume parameter corresponding to the retrieved time session in accordance with time indicated by the timing unit 2 of the electronic device. Then, it proceeds to Step S3.

In Step S3, the sound recognition module 40 receives and recognizes a sound signal around the electronic device. Then, it proceeds to Step S4.

In Step S4, the sound effects setting module 50 sets a corresponding sound output signal to be outputted by the speaker unit 3 according to the maximum sound volume parameter retrieved by the time session control module 30, the environmental characteristics parameter, the personalized characteristics parameter, and the sound signal recognized by the sound recognition module 40.

Referring to FIG. 2B, Step S2 comprises the following steps. In Step S20, the time session recognition module 300 recognizes the time session corresponding to the time indicated by the timing unit 2. Then, it proceeds to Step S21.

In Step S21, the time session recognition module 300 retrieves the maximum sound volume parameter corresponding to the retrieved time session from the table 301 of time session versus maximum sound volume.

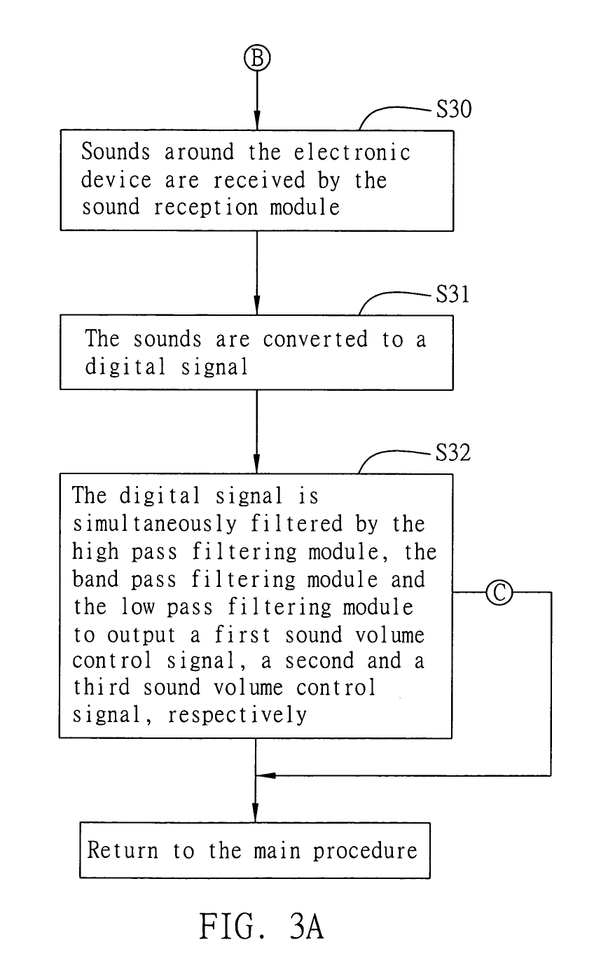

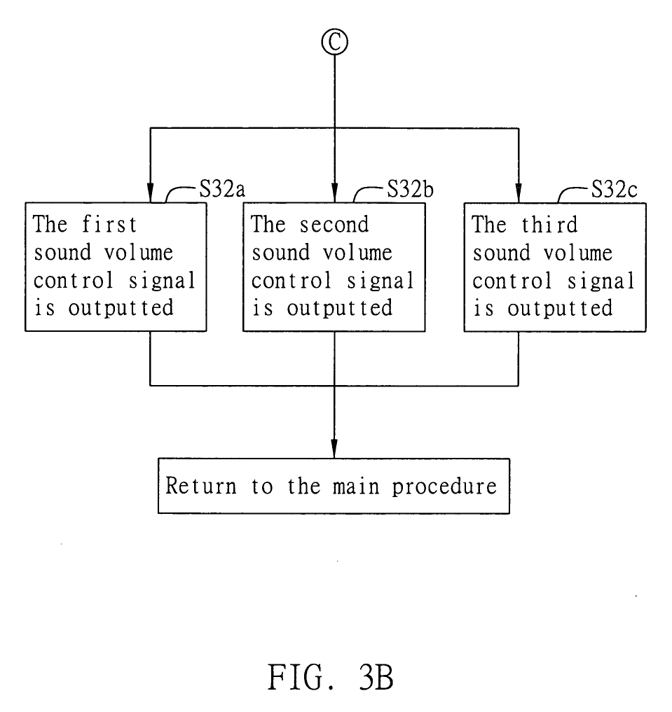

FIGS. 3A and 3B show flowcharts of a method of recognizing a sound in a surrounding environment via the sound recognition module 40 shown in FIG. 1A. Referring to FIG. 3A, Step S3 comprises the following steps. In Step S30, the sound reception module 400 receives sounds around the electronic device. Then, it proceeds to Step S31.

In Step S31, the A/D converting module 401 converts the sounds received by the sound reception module 400 to a digital signal. Then, it proceeds to Step S32.

In Step S32, the high pass filtering module 402a, the band pass filtering module 402b and the low pass filtering module 402c simultaneously perform a filtering process on the digital signal outputted from the A/D converting module 401.

Referring to FIG. 3B, Step S32 comprises the following steps. In Step S32a, the ring recognition module 403 recognizes a filtered signal outputted from the high pass filtering module 402a and outputs a first sound volume control signal according to the recognition result. In Step S32b, the subtraction operating module 405 and the noise recognition module 404 process and recognize a filtered signal outputted from the band pass filtering module 402b so as to output a second sound volume control signal via the noise recognition module 404 according to the recognition result. In Step S32c, the noise recognition module 404 recognizes a filtered signal outputted from the low pass filtering module 402c and outputs a third sound volume control signal according to the recognition result. In this embodiment, Steps S32a, S32b and S32c are simultaneously performed. However, it should be understood that these steps can also be successively performed depending on practical requirements.

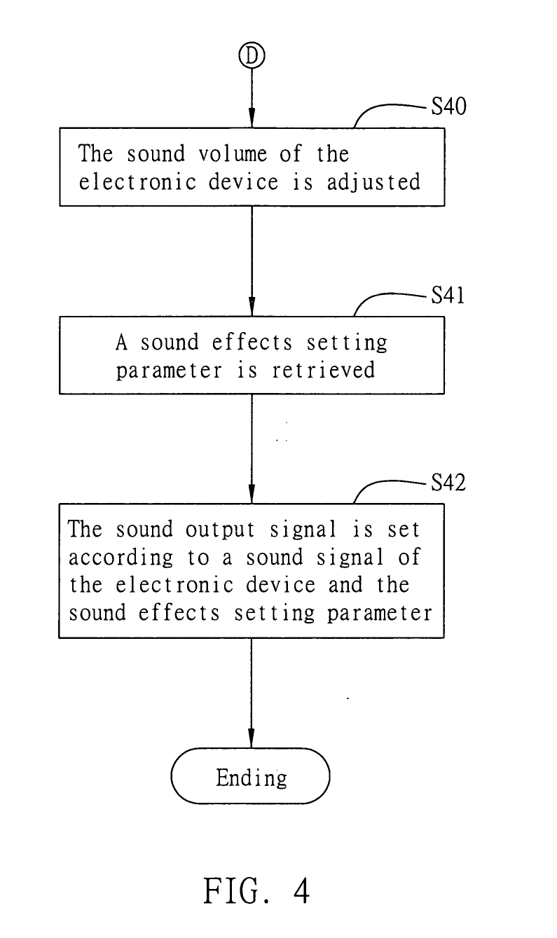

FIG. 4 shows a flowchart of a method of setting a sound via the sound effects setting module 50 shown in FIG. 1A.

Referring to FIG. 4, Step S4 comprises the following steps. In Step S40, the sound volume control module 501 adjusts the sound volume of the electronic device according to the first, second and third sound volume control signals outputted in Step S3. Then, it proceeds to Step S41.

In Step S41, the program memory unit 500a performs a match calculation according to the environmental characteristics parameter and the personalized characteristics parameter set via the setting module 10 and retrieves a corresponding sound effects setting parameter from the sound effects memory unit 500b. Then, it proceeds to Step S42.

In Step S42, the acoustic processing module 502 sets the sound output signal to be outputted by the speaker unit 3 according to the sound effects setting parameter and a sound signal of the electronic device generated in Step S40. The first sound volume control signal has priority over the second and third sound volume control signals. Thus, once the ring recognition module 403 has recognized a telephone ring and outputted the first sound volume control signal, the sound volume control module 501 is capable of automatically decreasing the sound volume of the electronic device. In this embodiment, steps S40, S41 and S42 are simultaneously performed. However, it should be understood that these steps can also be successively performed depending on practical requirements.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A sound control system applicable to an electronic device having a timing unit, the sound control system comprising:
a setting module for a user to set maximum sound volume parameters, an environmental characteristics parameter, and a personalized characteristics parameter, corresponding to different time sessions of a day, an environment where the electronic device is located, and the user's personality, respectively;
a parameter memory unit for storing the maximum sound volume parameters, the environmental characteristics parameters, and the personalized characteristics parameters, which are set by the user via the setting module;
a time session control module for retrieving from the parameter memory unit a corresponding time session and the maximum sound volume parameter corresponding to the retrieved time session in accordance with time indicated by the timing unit;
a sound recognition module for receiving and recognizing a sound signal around the electronic device; and
a sound effects setting module for setting a corresponding sound output signal to be outputted by a speaker unit connected to the sound control system according to the environmental characteristics parameter, the personalized characteristics parameter, the maximum sound volume parameter retrieved by the time session control module, and the sound signal recognized by the sound recognition module.

2. The sound control system of claim 1, wherein the time session control module comprises a time session recognition module and a table of time session versus maximum sound volume.

3. The sound control system of claim 2, wherein the time session recognition module recognizes the time session corresponding to the time indicated by the timing unit and retrieves the maximum sound volume parameter corresponding to the time session from the table of time session versus maximum sound volume.

4. The sound control system of claim 1, wherein the sound recognition module comprises a sound reception module, an A/D converting module, a signal processing module, a ring recognition module, a noise recognition module, and a subtraction operating module; and the sound effects setting module comprises a sound volume control module, a tone quality setting module, and an acoustic processing module.

5. The sound control system of claim 4, wherein the signal processing module comprises a high pass filtering module, a band pass filtering module, and a low pass filtering module.

6. The sound control system of claim 5, wherein a filtering parameter of each of the filtering modules is dynamically adjusted according to present sound volume of the electronic device.

7. The sound control system of claim 5, wherein the ring recognition module recognizes a high frequency sound signal that is obtained by the high pass filtering module filtering the sound signal, and outputs a first sound volume control signal according to the recognition result.

8. The sound control system of claim 7, wherein the ring recognition module recognizes a telephone ring generated in the environment and outputs the first sound volume control signal, such that the sound volume control module decreases sound volume of the electronic device according to the first sound volume control signal.

9. The sound control system of claim 4, wherein the tone quality setting module comprises a program memory unit and a sound effects memory unit.

10. The sound control system of claim 9, wherein the program memory unit performs a match calculation according to the environmental characteristics parameter and the personalized characteristics parameter set via the setting module, and retrieves a corresponding sound effects setting parameter from the sound effects memory unit.

11. The sound control system of claim 10, wherein the acoustic processing module sets the sound output signal to be outputted by the speaker unit according to the sound effects setting parameter outputted from the tone quality setting module and a sound signal of the electronic device outputted from the sound volume control module.

12. The sound control system of claim 5, wherein the band pass filtering module filters the sound signal to obtain successive background sounds in the environment.

13. The sound control system of claim 12, wherein the subtraction operating module subtracts a sound signal generated by the electronic device from the successive background sounds to obtain successive noises in the environment.

14. The sound control system of claim 13, wherein the noise recognition module recognizes the noises in the environment and outputs a second sound volume control signal according to the recognition result.

15. The sound control system of claim 5, wherein the low pass filtering module filters the sound signal to obtain successive noises outside the environment.

16. The sound control system of claim 15, wherein the noise recognition module recognizes the noises outside the environment and outputs a third sound volume control signal according to the recognition result.

17. The sound control system of claim 4, wherein the ring recognition module further comprises a ring memory module for storing a telephone ring used by the user, such that the stored telephone ring serves as a basis for the ring recognition module to recognize an incoming telephone ring in the environment.

18. The sound control system of claim 17, wherein the ring memory module is stored with a plurality of different rings each being inputted several times, and the ring recognition module identifies characteristics of each of the rings for use as a basis in ring recognition.

19. A sound control method applicable to an electronic device having a timing unit, the method comprising the steps of:
providing a setting module for a user to set maximum sound volume parameters, an environmental characteristics parameter, and a personalized characteristics parameter, corresponding to different time sessions of a day, an environment where the electronic device is located, and the user's personality, respectively; and storing the maximum sound volume parameters, the environmental characteristics parameter, and the personalized characteristics parameter in a parameter memory unit;
retrieving via a time session control module from the parameter memory unit a corresponding time session and the maximum sound volume parameter corresponding to the retrieved time session in accordance with time indicated by the timing unit;
receiving and recognizing a sound signal around the electronic device via a sound recognition module; and
setting a corresponding sound output signal via a sound effects setting module according to the maximum sound volume parameter retrieved by the time session control module, the environmental characteristics parameter, the personalized characteristics parameter, and the sound signal recognized by the sound recognition module.
